(19) United States
(12) Patent Application Publication
(10) Pub. No.: US 2017/0084788 A1
(43) Pub. Date: Mar. 23, 2017

(54) SEMICONDUCTOR LIGHT-EMITTING ELEMENT AND PRODUCTION METHOD THEREFOR

(71) Applicant: USHIO DENKI KABUSHIKI KAISHA, Tokyo (JP)

(72) Inventors: Toru SUGIYAMA, Himeji-shi (JP); Masashi TSUKIHARA, Himeji-shi (JP); Kohei MIYOSHI, Himeji-shi (JP)

(73) Assignee: USHIO DENKI KABUSHIKI KAISHA, Tokyo (JP)

(21) Appl. No.: 15/126,535

(22) PCT Filed: Mar. 10, 2015
(86) PCT No.: PCT/JP2015/056951

§ 371 Date: Sep. 15, 2016

(30) Foreign Application Priority Data
Mar. 17, 2014 (JP) 2014-054136

(51) Int. Cl. H01L 33/40; H01L 33/06; H01L 33/32; H01L 33/00

(52) U.S. Cl. CPC H01L 33/405; H01L 33/007; H01L 33/0095; H01L 33/0079; H01L 33/06; H01L 33/32; H01L 2933/0016

(57) ABSTRACT

The purpose of the present invention is to provide a semiconductor light-emitting element with further enhanced light extraction efficiency while ensuring horizontal widening of current flowing through an active layer. This method for producing a semiconductor light-emitting element according to the present invention includes: a step (a) for forming a semiconductor layer including an active layer on an upper layer of a growth substrate; a step (b) for forming a first metal layer on a top surface of the semiconductor layer; a step (c) for forming a second metal layer on a portion of a top surface of the first metal layer without preforming annealing after the step (b); and a step (d) for performing annealing after the step (c).

### TECHNICAL FIELD

The present invention relates to a semiconductor light-emitting element and a production method therefor.

### BACKGROUND ART

In the prior art, in a light-emitting element using a nitride semiconductor, there has been developed a light-emitting element having a structure in which an electrode for feeding power to a p-type semiconductor layer and an electrode for feeding power to an n-type semiconductor layer are arranged at positions opposite to an active layer, and namely, a light-emitting element having a so-called “vertical structure” has been developed. When the light-emitting element having the vertical structure is produced, the n-type semiconductor layer, the active layer, and the p-type semiconductor layer are arranged sequentially from the bottom on a sapphire substrate. Then, after a support substrate formed of Si or CuW is bonded to the p-type semiconductor layer side, the sapphire substrate is removed. A surface of the element is the n-type semiconductor layer, an electrode (n-side electrode) is provided on the n-type semiconductor side, and a wire which is a power feed wire is connected to the n-side electrode, so that a voltage is supplied. In the vertical structure, when a voltage is applied between an electrode (p-side electrode) on the p-type semiconductor layer side and the n-side electrode, current flows from the p-side electrode to the n-side electrode through the active layer, so that the active layer emits light.

The p-side electrode and the n-side electrode are arranged to have a positional relationship in which the p-side electrode and the n-side electrode face each other in a direction perpendicular to a surface of the support substrate (this direction is hereinafter also referred to as the “vertical direction”). Thus, when a voltage is applied between the both electrodes, a current path in the vertical direction in which the voltage flows almost by the shortest distance from the p-side electrode toward the n-side electrode is formed. At this time, almost all current flows through a region in the active layer located vertically below the n-side electrode, and little current flows in other regions in the active layer. As a result, there is a problem that the light-emitting region is restricted to lower the light emission efficiency. In order to solve this problem, various measures have been taken. For example, the following Patent Document 1 discloses a constitution in which an insulating layer is provided at a position immediately below the n-side electrode for the purpose of widening current in a direction parallel to a substrate surface of a support substrate.

### PRIOR ART DOCUMENT

### Patent Document

Patent Document 1: Japanese Patent No. 4207781

### SUMMARY OF THE INVENTION

### Problems to be Solved by the Invention

FIG. 10 is a schematic cross-sectional view of a semiconductor light-emitting element disclosed in Patent Document 1. A conventional semiconductor light-emitting element 90 is constituted to include, on a support substrate 91, a conductive layer 92, a reflective film 93, an insulating layer 94, a reflective electrode 95, a semiconductor layer 99, and an n-side electrode 100. The semiconductor layer 99 has a p-type semiconductor layer 96, an active layer 97 formed on an upper layer of the p-type semiconductor layer 96, and an n-type semiconductor layer 98 formed on an upper layer of the active layer 97. The reflective electrode 95 is an electrode corresponding to the above-described “p-side electrode”.

The insulating layer 94 is formed in a region including a position vertically below a position where the n-side electrode 100 is formed. Although the reflective film 93 formed of a metal material is formed on a lower layer of the insulating layer 94, the reflective film 93 does not have ohmic properties and fails to function as an electrode. On the other hand, the reflective electrode 95 is formed of a metal material and functions as an electrode (p-side electrode) when an ohmic contact between the reflective electrode 95 and the p-type semiconductor layer 96 is realized.

When a voltage is applied between the support substrate 91 and the n-side electrode 100, since the insulating layer 94 is provided at a position vertically below the n-side electrode 100, almost all current is prevented from vertically flowing in the active layer 97 in a region vertically below the n-side electrode 100. Namely, after current passes through the reflective electrode 95, the current flows toward the n-side electrode 100 while widening in a direction (horizontal direction) parallel to a surface of the support substrate 91. Consequently, an effect of horizontally widening the current flowing in the active layer 97 is obtained, and a light-emitting region in the active layer 97 is widened in the horizontal direction.

The reflective electrode 95 serves a purpose of reflecting, among light emitted by the active layer 97, the light radiated in a direction (downward in the drawing) downward the support substrate 91 and extracting the light on the n-type semiconductor layer 98 side (upward in the drawing), thereby enhancing light extraction efficiency. The reflective film 93 is formed for achieving the same object. Light passing through a site where the reflective electrode 95 is not formed and travelling downward is reflected by the reflective film 93 to change its travelling direction to the n-type semiconductor layer 98 side, whereby the light extraction efficiency is enhanced.

However, when light radiated downward from the active layer 97 is reflected by the reflective film 93 to be extracted upward, this light passes into the insulating film 94 twice before and after being reflected by the reflective film 93. Consequently, when light passes into the insulating film 94, several % of light is absorbed by the insulating film 94. More specifically, approximately 3 to 4% of light is absorbed until light having passed from the active layer 97 to the insulating film 94 reaches the reflective film 93. Further, 3 to 4% of light is absorbed until light reflected by the reflective film 93 and having passed through the insulating film 94 is extracted to the outside on the n-type semiconductor layer 98 side.

Namely, in the conventional constitution, among light radiated from the active layer 97, the light radiated downward is reflected to enhance the light extraction efficiency. However, since a portion of the light is absorbed into the insulating film 94, it cannot be said that the light extraction efficiency is sufficiently enhanced.

In view of the above problem, an object of the present invention is to provide a semiconductor light-emitting element with further enhanced light extraction efficiency while ensuring horizontal widening of current flowing through an active layer.

### Means for Solving the Problem

A method for producing a semiconductor light-emitting element according to the present invention includes

a step (a) of forming a semiconductor layer including an active layer on an upper layer of a growth substrate,

a step (b) of forming a first metal layer on a top surface of the semiconductor layer,

a step (c) of forming a second metal layer on a portion of a top surface of the first metal layer without preforming annealing after the step (b), and

a step (d) of performing annealing after the step (c).

When annealing is performed in such a state that the second metal layer is formed on a portion of the top surface of the first metal layer, in the first metal layer, between a site where the second metal layer is formed on the top surface and a site where the top surface is exposed, a difference in amount of oxygen introduced during annealing occurs. As a result, a metal oxide layer constituting an ohmic contact is formed at an interface (hereinafter referred to as the “first interface”) between the first metal layer and a semiconductor layer in a region of the first metal layer with an exposed top surface. On the other hand, since a sufficient amount of oxygen is not supplied at an interface (hereinafter referred to as the “second interface”) between the first metal layer and the semiconductor layer in a region of the first metal layer whose top surface is covered by the second metal layer, a metal oxide layer formed is thin as compared with the first interface, or the metal oxide layer is not formed at all. As a result, in the second interface, the ohmic contact is not formed as compared with the first interface, so that resistance becomes high.

Namely, according to the above method, at an interface between the semiconductor layer and the first metal layer, a resistance value can be made different between the region where the second metal layer is formed and the region where the second metal layer is not formed. Thus, when annealing is performed after the second metal layer is previously formed in a region where a current is not desired to flow in a direction perpendicular to a surface of a substrate, a resistance of the region can be made higher than that in the adjacent region. Accordingly, current easily flows in a direction parallel to a substrate surface. Consequently, since current flowing in the active layer can be widened in a direction (horizontal direction) parallel to the substrate surface, the light extraction efficiency can be enhanced.

In the conventional semiconductor light-emitting element described with reference to FIG. 10, by virtue of the provision of the insulating layer 94 formed on the upper layer of the reflective film 93, the effect of horizontally widening the current flowing in the active layer 97 is achieved. However, since the insulating layer 94 is formed on the upper layer of the reflective film 93, light radiated from the active layer 97 is forced to pass into the insulating layer 94 twice before being reflected by the reflective film 93 and then extracted. Due to this, several % of light is absorbed in the insulating layer 94.

On the other hand, according to a semiconductor light-emitting element produced by the above method, resistance at an interface between the first metal layer and the semiconductor layer is made different depending on a place, whereby the effect of horizontally widening current flowing into the active layer is achieved. Thus, an insulating layer may not be necessary provided between the first metal layer and the semiconductor layer. Consequently, before light radiated from the active layer to the substrate side is reflected by the first metal layer and then extracted to a light extraction surface, the light is not absorbed by the insulating layer, so that the light extraction efficiency can be enhanced as compared with the prior art.

The step (a) may have a step of forming an n-type or p-type first semiconductor layer on the upper layer of the growth substrate, a step of forming the active layer on an upper layer of the first semiconductor layer, and a step of forming, on an upper layer of the active layer, a second semiconductor layer of a conductive type different from that of the first semiconductor layer. The production method may include, after the step (d), a step (e) for forming a support substrate on the upper layers of the first metal layer and the second metal layer, a step (f) for exfoliating the growth substrate, and a step (g) for forming a first electrode on a top surface of the first semiconductor layer on the opposite side of the active layer at a position facing the second metal layer in a direction perpendicular to a surface of the support substrate.

According to the above method, a contact resistance at an interface between the first metal layer and the semiconductor layer (second semiconductor layer) is high at a position facing the first electrode in a direction perpendicular to a surface of the support substrate (this direction is hereinafter also referred to as the “vertical direction”), as compared with a position not facing the first electrode in the vertical direction. Thus, current can be made less likely to flow in the vertical direction between the first electrode and the first metal layer, and the effect of horizontally widening current flowing into the active layer is obtained.

The first metal layer may be formed of a material containing Ag, and the second metal layer may be formed of a material containing at least one of Ti, Pt, Mo, Rh, Cu, Au, Mg, Ni, and W.

The semiconductor light-emitting element according to the present invention is a semiconductor light-emitting element having, on a support substrate, an n-type or p-type first semiconductor layer, a second semiconductor layer of a conductive type different from that of the first semiconductor layer, and an active layer formed between the first semiconductor layer and the second semiconductor layer.

The semiconductor light-emitting element includes

a first electrode formed in contact with a top surface of the first semiconductor layer,

a first metal layer formed in contact with a bottom surface of the second semiconductor layer, and

a second metal layer formed in contact with a bottom surface of the first metal layer at a position facing the first electrode in a direction perpendicular to a surface of the support substrate.

In this semiconductor light-emitting element, at an interface between the first metal layer and the second semiconductor layer, a resistance at a first interface at a position facing the second metal layer in the direction perpendicular to the surface of the support substrate is higher than a resistance at a second interface at a position not facing the second metal layer in the direction.

The entire top surface of the first metal layer may be in contact with the bottom surface of the second semiconductor layer.

A total area of a region where the second metal layer is in contact with the bottom surface of the first metal layer may be not more than 60% of an area of the p-type semiconductor layer. According to this constitution, the effect of further enhancing the light extraction efficiency is obtained.

A contact area between the first semiconductor layer and the first electrode may be not more than 50% of a contact area between the second metal layer and the first metal layer at the position facing the first electrode in the direction perpendicular to the surface of the support substrate. According to this constitution, the effect of further enhancing the light extraction efficiency is obtained.

The first semiconductor layer may be constituted of an n-type semiconductor layer, and the second semiconductor layer may be constituted of a p-type semiconductor layer. In this case, the first electrode corresponds to an n-side electrode, and the second electrode corresponds to a p-side electrode.

### Effect of the Invention

The present invention achieves a semiconductor light-emitting element with further enhanced light extraction efficiency as compared with the prior art while ensuring horizontal widening of current flowing through an active layer.

### BRIEF DESCRIPTION OF THE DRAWINGS

FIG. 1A is a cross-sectional view schematically showing a constitution of an embodiment of a semiconductor light-emitting element.

FIG. 1B is a plan view schematically showing the constitution of the embodiment of the semiconductor light-emitting element.

FIG. 1C is a partial view of FIG. 1A.

FIG. 2A is a part of a step sectional view of an embodiment of a semiconductor light-emitting element.

FIG. 2B is a part of a step sectional view of the embodiment of the semiconductor light-emitting element.

FIG. 2C is a part of a step sectional view of the embodiment of the semiconductor light-emitting element.

FIG. 2D is a part of a step sectional view of the embodiment of the semiconductor light-emitting element.

FIG. 2E is a part of a step sectional view of the embodiment of the semiconductor light-emitting element.

FIG. 2F is a part of a step sectional view of the embodiment of the semiconductor light-emitting element.

FIG. 2G is a part of a step sectional view of the embodiment of the semiconductor light-emitting element.

FIG. 2H is a part of a step sectional view of the embodiment of the semiconductor light-emitting element.

FIG. 2I is a part of a step sectional view of the embodiment of the semiconductor light-emitting element.

FIG. 2J is a part of a step sectional view of the embodiment of the semiconductor light-emitting element.

FIG. 3A is a cross-sectional view schematically showing a constitution of an evaluation element of Example 1.

FIG. 3B is a cross-sectional view schematically showing the constitution of the evaluation element of Example 1.

FIG. 4A is a cross-sectional view schematically showing a constitution of an evaluation element of Example 2.

FIG. 4B is a cross-sectional view schematically showing the constitution of the evaluation element of Example 2.

FIG. 5 is a table showing results of contact resistivity in the evaluation elements of Examples 1 and 2 for each annealing temperature.

FIG. 6A is a cross-sectional view schematically showing a structure of a semiconductor light-emitting element of Comparative Example 1.

FIG. 6B is a cross-sectional view schematically showing a structure of a semiconductor light-emitting element of Comparative Example 2.

FIG. 6C is a cross-sectional view schematically showing a structure of a semiconductor light-emitting element of Comparative Example 3.

FIG. 7 is a graph showing I-L characteristics (current-light output characteristics) of each of the semiconductor light-emitting elements of Example 3 and Comparative Examples 1 to 3.

FIG. 8 is a table comparing light outputs of semiconductor light-emitting elements of Examples 4 to 7.

FIG. 9 is a table comparing light outputs of semiconductor light-emitting elements of Examples 8 to 11 and the semiconductor light-emitting element of Comparative Example 2.

FIG. 10 is a cross-sectional view schematically showing a constitution of a conventional semiconductor light-emitting element.

### MODE FOR CARRYING OUT THE INVENTION

The semiconductor light-emitting element of the present invention will be described with reference to the drawings. In each drawing, the dimensional ratio of the drawings does not necessarily coincide with the actual dimensional ratio. Hereinafter, a description AlGaN is synonymous with a description AlₘGa₁₋ₘN (0<m<1), and it is described such that a description of a composition ratio of Al and Ga is just omitted, and this does not aim to limit the present invention to a case where the composition ratio of Al and Ga is 1:1. The same thing applies to descriptions InGaN, InGaP, and AlGaInP.

[Structure]

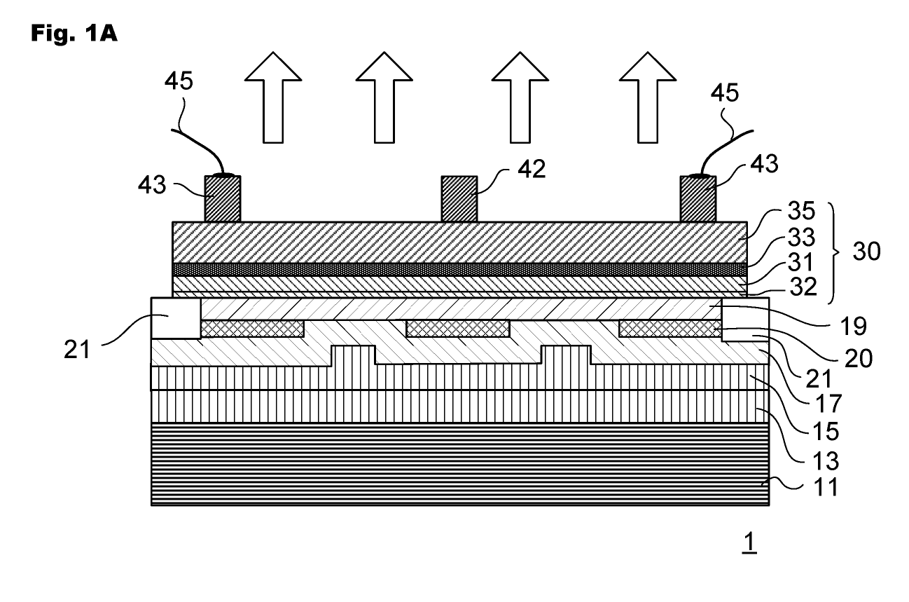

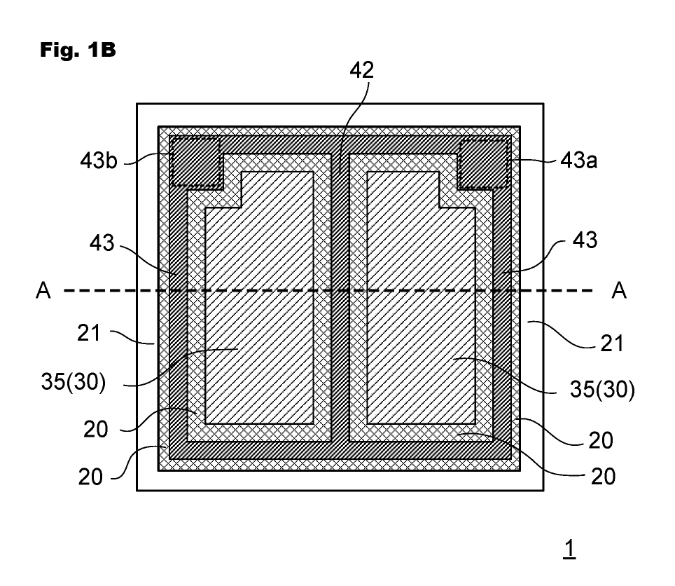

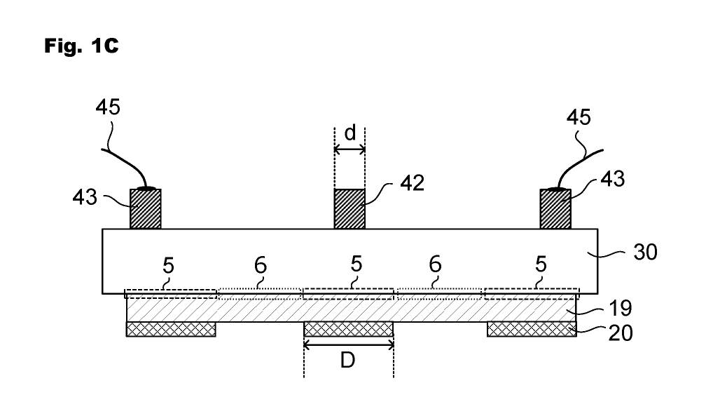

FIG. 1A is a cross-sectional view schematically showing a constitution of an embodiment of a semiconductor light-emitting element. A semiconductor light-emitting element 1 is constituted to include a support substrate 11, a first metal layer 19, a second metal layer 20, a semiconductor layer 30, and an n-side electrode (42, 43). FIG. 1B is a schematic plan view of the semiconductor light-emitting element 1 as viewed from a top surface thereof. FIG. 1A corresponds to an A-A line cross-sectional view of FIG. 1B. FIG. 1C illustrates a portion of FIG. 1A for convenience of description. In this embodiment, the n-side electrode (42, 43) correspond to a “first electrode”.

A more detailed constitution of the semiconductor light-emitting element 1 is as follows. The semiconductor light-emitting element 1 has a solder layer (13, 15) on an upper layer of the support substrate 11 and further has a solder diffusion preventing layer 17 on an upper layer of the solder layer (13, 15). The semiconductor light-emitting element 1 has a first metal layer 19 and a second metal layer 20 on an upper layer of the solder diffusion preventing layer 17. The second metal layer 20 is formed in contact with a bottom surface (surface on the support substrate 11 side) of the first metal layer 19. In an example of FIG. 1A, the second metal layer 20 is formed at a position where the second metal layer 20 is held between the first metal layer 19 and the solder diffusion preventing layer 17.

The semiconductor light-emitting element 1 has an insulating layer 21 on the upper layer of the solder diffusion preventing layer 17, and the insulating layer 21 is formed to be located outside the first metal layer 19 and the second metal layer 20. The semiconductor layer 30 has a p-type semiconductor layer 32, a p-type semiconductor layer 31, an active layer 33, and an n-type semiconductor layer 35. The p-type semiconductor layer 32 is formed in contact with a top surface (a surface on the opposite side of the support substrate 11) of the first metal layer 19. The p-type semiconductor layer 31 is formed on an upper layer of the p-type semiconductor layer 32. The active layer 33 is formed on an upper layer of the p-type semiconductor layer 31. The n-type semiconductor layer 35 is formed on an upper layer of the active layer 33. The n-side electrode (42, 43) is formed on an upper layer of the n-type semiconductor layer 35. In this embodiment, the n-type semiconductor layer 35 corresponds to a “first semiconductor layer”, and the p-type semiconductor layer 31 and the p-type semiconductor layer 32 correspond to “second semiconductor layers”.

(Support Substrate 11)

The support substrate 11 is constituted of a conductive substrate such as CuW, W, or Mo or a semiconductor substrate such as Si.

(Solder Layer 13, Solder Layer 15, and Solder Diffusion Preventing Layer 17)

The solder layer 13 and the solder layer 15 are formed of, for example, Au—Sn, Au—In, Au—Cu—Sn, Cu—Sn, Pd—Sn, Sn, or the like. As will be described later, these solder layer 13 and the solder layer 15 are formed by bonding the two with each other after the solder layer 13 formed on the support substrate 11 and the solder layer 15 formed on another substrate (a growth substrate 61 to be described later) are placed to face each other.

The solder diffusion preventing layer 17 is formed of, for example, a Pt-based metal (an alloy of Ti and Pt), W, Mo, Ni, or the like. As will be described later, the solder diffusion preventing layer 17 functions to prevent decrease in the light emission efficiency. This is because in bonding through the solder layers (13, 15), the solder diffusion preventing layer 17 has a function to prevent diffusion of the material constituting the solder layers (13, 15) to the first metal layer 19 side. If the material constituting the solder layers (13, 15) diffuses to the first metal layer 19 side, the reflectivity in the first metal layer 19 of light radiated from the active layer 33 toward the first metal layer 19 is reduced.

Any of the solder layer 13, the solder layer 15, and the solder diffusion preventing layer 17 are formed of a highly conductive material (metal material).

(First Metal Layer 19 and Second Metal Layer 20)

The first metal layer 19 is formed of, for example, Ag, an Ag alloy (such as Ni/Ag), or the like. The first metal layer 19 is in contact with the p-type semiconductor layer 32 and constitutes a “p-side electrode”. It is assumed in the semiconductor light-emitting element 1 that the light radiated from the active layer 33 is extracted in the upward direction (the n-type semiconductor layer 35 side) of FIG. 1A. The first metal layer 19 functions to reflect upward the light radiated downward from the active layer 33 and thereby enhance the light emission efficiency. The upward arrow in FIG. 1A shows a light extraction direction.

The first metal layer 19 is formed on a lower layer of the p-type semiconductor layer (31, 32). A region where the first metal layer 19 is formed includes a region vertically below the n-side electrode (42, 43). As shown in FIG. 1A, in this embodiment, the first metal layer 19 is formed such that the entire top surface of the first metal layer 19 is in contact with the p-type semiconductor layer 32. However, this is just an example, and a partial region of the top surface of the first metal layer 19 may not be in contact with the p-type semiconductor layer 32.

The second metal layer 20 is formed of a material containing at least one of Ti, Pt, Mo, Rh, Cu, Au, Mg, Ni, and W. The second metal layer 20 is formed on a lower layer of the first metal layer 19. The second metal layer 20 may not necessarily be formed of a highly reflective material comparable to the first metal layer 19. This is because most of the light radiated downward from the active layer 33 is reflected upward in the first metal layer 19. The second metal layer 20 may be formed of the same material as the solder diffusion preventing layer 17. However, as will be described later in the section “Production Method”, even if the second metal layer 20 and the solder diffusion preventing layer 17 are formed of the same material, after a step of forming the second metal layer 20 is carried out, the semiconductor light-emitting element 1 is formed through a step of executing annealing and a step of forming the solder diffusion preventing layer 17, and therefore, a step of forming a metal layer formed of the same material is required to be performed a plurality of times.

The second metal layer 20 is formed such that a top surface of the second metal layer 20 is in contact with a bottom surface of the first metal layer 19. However, the top surface of the second metal layer 20 is not in contact with the entire bottom surface of the first metal layer 19. As shown in FIG. 1A, the bottom surface of the first metal layer 19 has a region in contact with the second metal layer 20 and a region in contact with the solder diffusion preventing layer 17.

The second metal layer 20 is formed at a position facing the n-side electrode (42, 43) in a direction perpendicular to a surface of the support substrate 11. As shown in FIG. 1C, the second metal layer 20 is formed such that a width D of the second metal layer 20 is larger than a width d of the n-side electrode (42, 43).

In this embodiment, the entire top surface of the first metal layer 19 is in contact with the semiconductor layer 30 (the p-type semiconductor layer 32). As will be described later in the section “Production Method”, in producing the semiconductor light-emitting element 1, after the semiconductor layer 30 is formed, the first metal layer 19 is formed, and after that, the second metal layer 20 is continuously formed without executing annealing. As a result, a difference in resistance at an interface between the first metal layer 19 and the semiconductor layer 30 is provided between a site where the second metal layer 20 is formed and a site where the second metal layer 20 is not formed. More particularly, at the interface between the first metal layer 19 and the semiconductor layer 30, when a first interface 5 facing the second metal layer 20 in a direction perpendicular to the surface of the support substrate 11 is compared with a second interface 6 not facing the second metal layer 20 in the direction perpendicular to the surface of the support substrate 11, a resistance at the first interface 5 is higher than that at the second interface 6 (see, FIG. 1C).

Under this constitution, when a voltage is applied between the support substrate 11 and the n-side electrode (42, 43), a current path in which the current flows to the n-side electrode (42, 43) through the support substrate 11, the solder layers (13, 15), the solder diffusion preventing layer 17, the first metal layer 19, and the semiconductor layer 30 is formed. Since the second metal layer 20 is formed of a metal material, it is assumed that the conductivity is high as in the first metal layer 19. However, vertically above the site where the second metal layer 20 is formed, a contact resistance between the semiconductor layer 30 and the interface (the first interface 5) of the first metal layer 19 is higher than a contact resistance between the semiconductor layer 30 at another position and the interface (the second interface 6) of the first metal layer 19. Thus, when a voltage is applied to the semiconductor light-emitting element 1, a current flowing from the second metal layer 20 toward the n-side electrode (42, 43) is less likely to flow in the direction perpendicular to the surface of the support substrate 11.

Namely, a current passing through the first metal layer 19 easily flows to the semiconductor layer 30 through the second interface 6 where the resistance is lower than that of the first interface 5. The second interface 6 is located not facing the n-side electrode (42, 43) in the direction perpendicular to the surface of the support substrate 11. Thus, when a current flowing into the semiconductor layer 30 through the second interface 6 flows toward the n-side electrode (42, 43), the current flows into the semiconductor layer 30 while widening in a direction parallel to the surface of the support substrate 11, that is, the horizontal direction. As a result, since the current can flow into the active layer 33 over a wide range, the light emission efficiency can be enhanced.

(Insulating Layer 21)

The insulating layer 21 is formed of, for example, SiO₂, SiN, Zr₂O₃, AlN, Al₂O₃, or the like. In this embodiment, the insulating layer 21 is formed outside the first metal layer 19 and the second metal layer 20, and a portion of the insulating layer 21 is located outside the semiconductor layer 30. As will be described later in the section “Production Method”, the insulating layer 21 functions as an etching stopper layer at the time of element separation.

In the insulating layer 21, a portion of the insulating layer 21 may be formed at a position vertically below the n-side electrode 43. In this case, the effect that a current flowing from the first metal layer 19 toward the n-side electrode 43 along the direction perpendicular to the surface of the support substrate 11 is made less likely to flow is obtained by the insulating layer 21, in addition to the first interface 5.

(Semiconductor Layer 30)

As described above, the semiconductor layer 30 is constituted to have the p-type semiconductor layer 32, the p-type semiconductor layer 31, the active layer 33, and the n-type semiconductor layer 35.

The p-type semiconductor layer 32 is formed of GaN, for example. The p-type semiconductor layer 31 is formed of AlGaN, for example. Each of the layers is doped with a p-type impurity such as Mg, Be, Zn, or C. The impurity concentration of the p-type semiconductor layer 32 is higher than that of the p-type semiconductor layer 31, and the p-type semiconductor layer 32 forms a contact layer.

The active layer 33 is formed of, for example, a semiconductor layer having a multiquantum well structure formed by repetition of a light-emitting layer formed of InGaN and a barrier layer formed of AlGaN. These layers may be either non-doped or doped to be p-type or n-type.

An n-type semiconductor layer is constituted of, for example, a multi-layered structure including a layer (electron supply layer) formed of AlGaN and a layer (protective layer) formed of GaN. At least the protective layer is doped with an n-type impurity such as Si, Ge, S, Se, Sn, or Te.

(n-Side Electrode 42 and n-Side Electrode 43)

The n-side electrode (42, 43) is an upper layer of the n-type semiconductor layer 35, is formed in a near end portion region and a near center region of the n-type semiconductor layer 35 in the cross-sectional view shown in FIG. 1A, and is formed of, for example, Cr—Au. The n-side electrode formed in the near end portion region corresponds to the n-side electrode 43, and the n-side electrode formed in the near center region corresponds to the n-side electrode 42. To the n-side electrode 43, for example, in regions 43a and 43b, a wire 45 formed of Au, Cu, or the like is connected (see FIG. 1B), and the other end of the wire 45 is connected to a power supply pattern of a substrate (the support substrate 11) on which the semiconductor light-emitting element 1 is disposed (not shown). Namely, the n-side electrode 43 functions as a power supply terminal of the semiconductor light-emitting element 1.

In the constitution shown in FIGS. 1A, 1B, and 1C, although the n-side electrode 42 is formed at one site in the near center region, a plurality of the n-side electrodes 42 may be formed to be arranged in a lattice form. Further, the n-side electrodes 42 may be formed to intersect each other and arranged in a mesh form.

As shown in FIG. 1B, the n-side electrode 42 and the n-side electrode 43 are connected in an upper layer of the semiconductor layer 30 and serve for widening a current path in a direction (horizontal direction) parallel to the surface of the support substrate 11. Namely, the n-side electrode 42 and the n-side electrode 43 are formed for the purpose of being in contact with a top surface of the n-type semiconductor layer 35 at the sites different from the site of the n-side electrode 43, constituting a power supply terminal, to flow a current over a wide range of the n-type semiconductor layer 35 in the horizontal direction at the time of energization and thereby flowing the current over a wide range in the active layer 33.

Although not illustrated, an insulating layer as a protective film may be formed on a side surface of the semiconductor layer 30. The insulating layer as the protective film is preferably formed of a material (such as SiO₂) having a light transmissivity. For the purpose of further enhancing the light extraction efficiency, fine concavoconvexes (mesa structure) may be formed on the top surface of the n-type semiconductor layer 35.

It will be described later with reference to Examples and Comparative Examples in the section “Verification” that by virtue of the semiconductor light-emitting element 1 of this embodiment, the light extraction efficiency is more enhanced than that in a conventional constitution while achieving a low-voltage drive equivalent to the conventional constitution.

[Production Method]

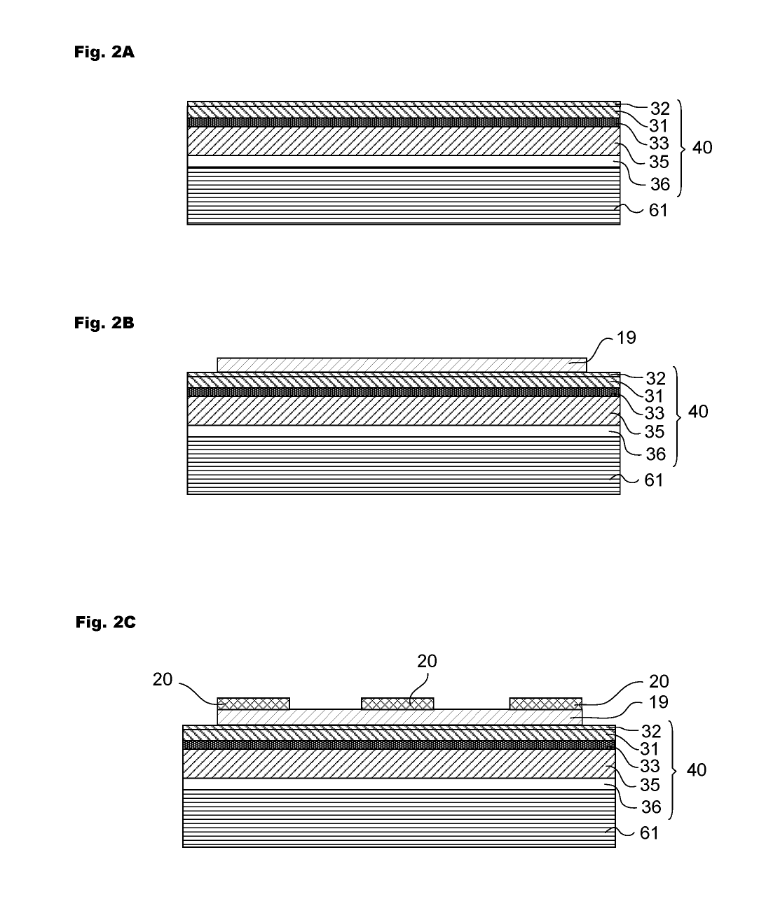

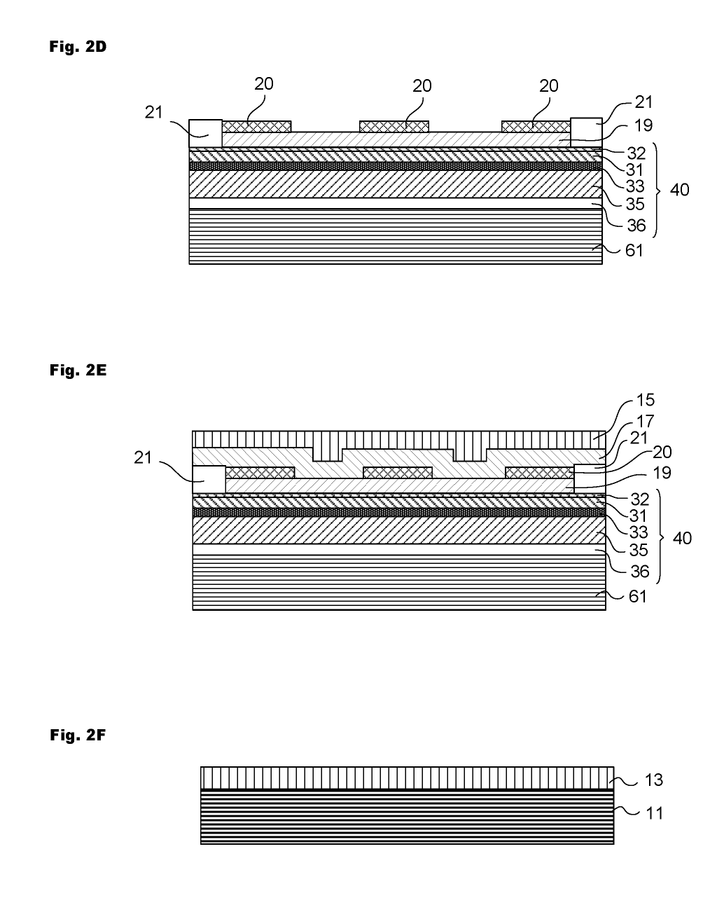

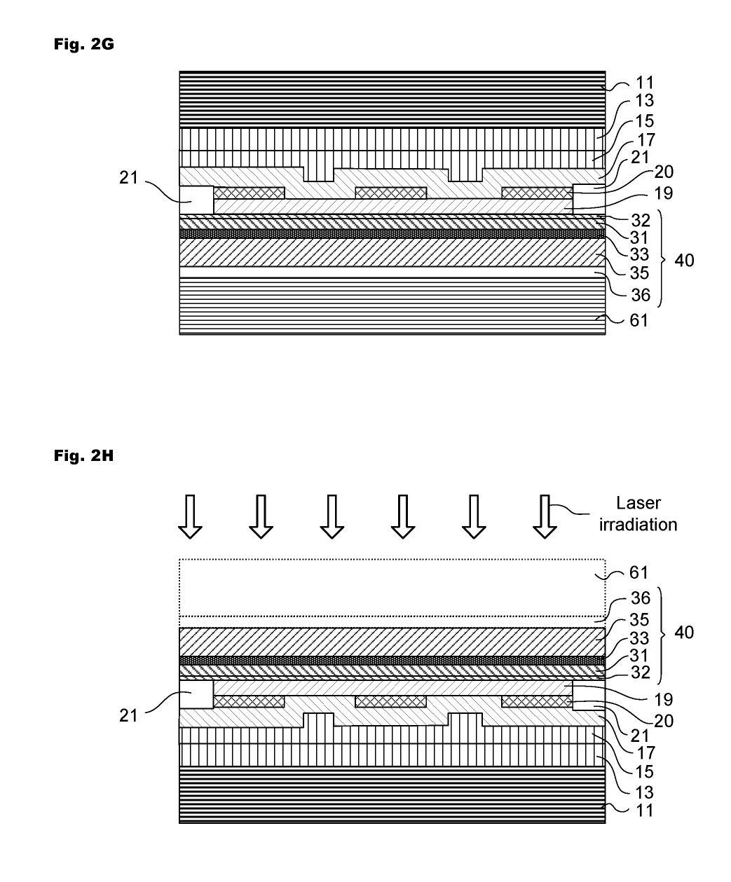

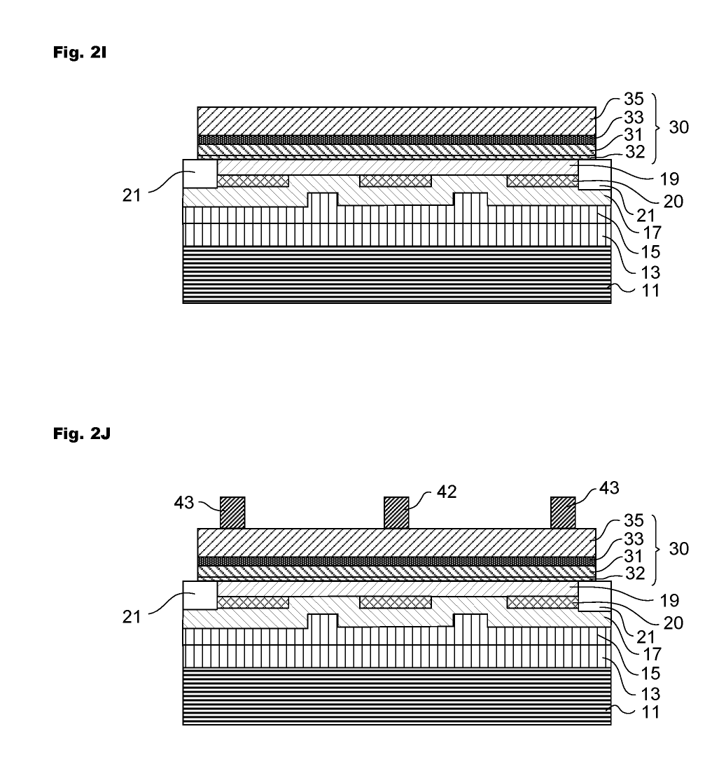

Next, one example of a production method for the semiconductor light-emitting element 1 will be described with reference to the step sectional views shown in FIGS. 2A to 2L. The production conditions and the dimensions such as the film thickness to be described below are merely examples, and the present invention is not limited to these numerical values alone.

(Step S1)

As shown in FIG. 2A, an epitaxial layer 40 is formed on a growth substrate 61. This STEP S1 is carried out, for example, according to the following procedure.

(Preparation of Growth Substrate 61)

First, a c-plane sapphire substrate used as the growth substrate 61 is cleaned. More specifically, this cleaning is carried out, for example, by placing the growth substrate 61 in a treatment furnace of an MOCVD (Metal Organic Chemical Vapor Deposition) apparatus and raising the temperature within the furnace to, for example, 1150° C. while allowing a hydrogen gas having a flow rate of 10 slm to flow within the treatment furnace. In this embodiment, this will be described as the case of epitaxially growing a semiconductor layer on a c-plane of a sapphire substrate.

(Formation of Non-Doped Layer 36)

Next, a low-temperature buffer layer formed of GaN is formed on a front surface of the growth substrate 61, and further a foundation layer formed of GaN is formed on an upper layer thereof. These low-temperature buffer layer and foundation layer correspond to a non-doped layer 36. A more specific method for forming the non-doped layer 36 is, for example, as follows.

First, the pressure within the furnace of the MOCVD apparatus is set to be 100 kPa, and the temperature within the furnace is set to be 480° C. Then, while allowing a nitrogen gas and a hydrogen gas each having a flow rate of 5 slm to flow as a carrier gas within the treatment furnace, trimethylgallium (TMG) having a flow rate of 50 μmol/min and ammonia having a flow rate of 250000 μmol/min are supplied for 68 seconds as a source material gas. This allows that a low-temperature buffer layer formed of GaN having a thickness of 20 nm is formed on the front surface of the c-plane sapphire substrate 61.

Next, the temperature within the furnace of the MOCVD apparatus is raised to 1150° C. Then, while allowing a nitrogen gas having a flow rate of 20 slm and a hydrogen gas having a flow rate of 15 slm to flow as a carrier gas within the treatment furnace, TMG having a flow rate of 100 μmol/min and ammonia having a flow rate of 250000 μmol/min are supplied for 30 minutes as a source material gas into the treatment furnace. This allows that a foundation layer formed of GaN having a thickness of 1.7 μm is formed on a front surface of the low-temperature buffer layer.

(Formation of n-Type Semiconductor Layer 35)

Next, the n-type semiconductor layer 35 formed of AlgaN is formed on the non-doped layer 36. A more specific method for forming the n-type semiconductor layer 35 is, for example, as follows.

In such a state that the temperature within the furnace is continuously set to 1150° C., the pressure within the furnace of the MOCVD apparatus is set to be 30 kPa. Then, while allowing a nitrogen gas having a flow rate of 20 slm and a hydrogen gas having a flow rate of 15 slm to flow as a carrier gas within the treatment furnace, TMG having a flow rate of 94 μmol/min, trimethylaluminum (TMA) having a flow rate of 6 μmol/min, ammonia having a flow rate of 250000 μmol/min, and tetraethylsilane having a flow rate of 0.025 μmol/min are supplied for 60 minutes as a source material gas. This allows that the n-type semiconductor layer 35 having a composition of Al_{0.06}Ga_{0.94}N, for example, having an Si concentration of 3×10¹⁹/cm³, and having a thickness of 2 μm is formed on an upper layer of the non-doped layer 36.

After that, supply of TMA is stopped, and the source material gas other than that is supplied for 6 seconds, whereby the n-type semiconductor layer 35 having a protective layer formed of n-type GaN having a thickness of 5 nm may be formed on an upper layer of an n-type AlGaN layer.

In the above description, although the case where the n-type impurity contained in the n-type semiconductor layer 35 is Si is described, as the n-type impurity, in addition to Si, Ge, S, Se, Sn, Te, or the like can be used.

(Formation of Active Layer 33)

Next, the active layer 33 having a multiquantum well structure in which a light-emitting layer formed of InGaN and a barrier layer formed of n-type AlGaN are periodically repeated is formed on the upper layer of the n-type semiconductor layer 35. A more specific method for forming the active layer 33 is, for example, as follows.

First, the pressure within the furnace of the MOCVD apparatus is set to be 100 kPa, and the temperature within the furnace is set to be 830° C. Then, while allowing a nitrogen gas having a flow rate of 15 slm and a hydrogen gas having a flow rate of 1 slm to flow as a carrier gas within the treatment furnace, a STEP of supplying TMG having a flow rate of 10 μmol/min, trimethylindium (TMI) having a flow rate of 12 μmol/min, and ammonia having a flow rate of 300000 μmol/min for 48 seconds as a source material gas is carried out. After that, a STEP of supplying TMG having a flow rate of 10 μmol/min, TMA having a flow rate of 1.6 μmol/min, tetraethylsilane having a flow rate of 0.002 μmol/min, and ammonia having a flow rate of 300000 μmol/min for 120 seconds into the treatment furnace is carried out. Subsequently, by repeating these two STEPs, the active layer 33 having a multiquantum well structure with 15 periods constructed by a light-emitting layer formed of InGaN having a thickness of 2 nm and a barrier layer formed of n-type AlGaN having a thickness of 7 nm is formed on the upper layer of the n-type semiconductor layer 35.

(Formation of p-Type Semiconductor Layer 31 and p-Type Semiconductor Layer 32)

Next, the p-type semiconductor layer 31 formed of AlGaN is formed on the upper layer of the active layer 33, and the p-type semiconductor layer 32 is formed on the upper layer of the p-type semiconductor layer 31. A more specific method for forming the p-type semiconductor layer 31 and the p-type semiconductor layer 32 is, for example, as follows.

The pressure within the furnace of the MOCVD apparatus is maintained to be 100 kPa and, while allowing a nitrogen gas having a flow rate of 15 slm and a hydrogen gas having a flow rate of 25 slm to flow as a carrier gas within the treatment furnace, the temperature within the furnace is raised to 1025° C. After that, TMG having a flow rate of 35 μmol/min, TMA having a flow rate of 20 μmol/min, ammonia having a flow rate of 250000 μmol/min, and bis(cyclopentadienyl)magnesium (CP₂Mg) having a flow rate of 0.1 μmol/min and used for doping a p-type impurity are supplied for 60 seconds as a source material gas into the treatment furnace. This allows that a hole supply layer having a composition of Al_{0.3}Ga_{0.7}N and having a thickness of 20 nm is formed on a front surface of the active layer 33. After that, by supplying the source material gas for 360 seconds after changing the flow rate of TMA to 4 μmol/min, a hole supply layer having a composition of Al_{0.13}Ga_{0.87}N and having a thickness of 120 nm is formed. The p-type semiconductor layer 31 is constituted of those hole supply layers. The p-type impurity concentration of the p-type semiconductor layer 31 is approximately 3×10¹⁹/cm³, for example.

Further, after that, supply of TMA is stopped, and the source material gas is supplied for 20 seconds after changing the flow rate of CP₂Mg to 0.2 μmol/min, whereby the p-type semiconductor layer 32 having a thickness of approximately 5 nm, having a p-type impurity concentration of approximately 1×10²⁰/cm³, and formed of p-type GaN is formed.

In this manner, the epitaxial layer 40 formed of the non-doped layer 36, the n-type semiconductor layer 35, the active layer 33, the p-type semiconductor layer 31, and the p-type semiconductor layer 32 is formed on the sapphire substrate 61. This STEP S1 corresponds to the step (a).

(Step S2)

Next, an activation treatment is carried out on the wafer obtained in the STEP S1. More specifically, an activation treatment at 650° C. for 15 minutes is carried out in a nitrogen atmosphere using an RTA (Rapid Thermal Anneal) apparatus.

(Step S3)

Next, as shown in FIG. 2B, the first metal layer 19 is formed at a predetermined site of the top surface of the p-type semiconductor layer 32. This embodiment shows the case where inside a region where the p-type semiconductor layer 32 is formed, the first metal layer 19 is formed on substantially the entire top surface of the p-type semiconductor layer 32. More specifically, for example, a film of Ni having a thickness of 0.7 nm and a film of Ag having a thickness of 150 nm are formed on the top surface of the p-type semiconductor layer 32 by a sputtering apparatus such that a site located vertically below a region where the n-side electrode 42 as a power supply terminal will be formed in a later STEP is included, whereby the first metal layer 19 is formed.

This STEP S3 corresponds to the step (b).

(Step S4)

Next, as shown in FIG. 2C, the second metal layer 20 is formed at a predetermined site of an upper layer of the first metal layer 19. In particular, the second metal layer 20 is formed at a site located vertically below a region where the n-side electrode (42, 43) will be formed in a later STEP. As one example of a specific method, a film of Ni having a thickness of 20 nm, a film of Ti having a thickness of 20 nm, and a film of Pt having a thickness of 30 nm are formed on the top surface of the first metal layer 19 by a sputtering apparatus, whereby the second metal layer 20 is formed.

This STEP S4 corresponds to the step (c).

(Step S5)

Annealing is performed in such a state that the second metal layer 20 is formed on a partial top surface of the first metal layer 19. More specifically, contact annealing at 400° C. for 2 minutes is carried out in a dry air atmosphere using an RTA apparatus.

As shown in FIG. 2C, the first metal layer 19 has a site where the top surface is exposed and a site where the top surface is covered by the second metal layer 20. When annealing is carried out in this state, a difference in amount of oxygen introduced during annealing occurs between the two sites. As a result, a metal oxide layer constituting an ohmic contact is formed at an interface (corresponding to the above-described “first interface 5”) between the lower layer of the first metal layer 19 at the site where the top surface is exposed and the p-type semiconductor layer 32. On the other hand, since a sufficient amount of oxygen is not supplied at an interface (corresponding to the above-described “second interface 6”) between the lower layer of the first metal layer 19 at the site where the top surface is covered by the second metal layer 20 and the p-type semiconductor layer 32, a metal oxide layer formed is thin as compared with the first interface 5, or the metal oxide layer is not formed at all. As a result, in the second interface 6, the ohmic contact is not formed as compared with the first interface 5, so that resistance becomes high.

Namely, in the STEP S4, it is preferable that the site where the second metal layer 20 is formed is located vertically above a region of the top surface of the first metal layer 19, where a resistance at the interface between the first metal layer 19 and the p-type semiconductor layer 32 is desired to be increased. More specifically, in the semiconductor light-emitting element 1, it is preferable that the second metal layer 20 is formed in a region where a current is desired to be made less likely to flow along the direction (vertical direction) perpendicular to a substrate surface of the support substrate 11. As described above, in this embodiment, in the later step, the second metal layer 20 is formed at the site located vertically below the region where the n-side electrode (42, 43) is formed. Thus, the first interface 5 formed through this STEP S5 is located facing the n-side electrode (42, 43) in the vertical direction once it is formed as the semiconductor light-emitting element 1. As a result, the current becomes less likely to flow in the vertical direction in the semiconductor layer 30, and the path of the current flowing into the active layer 33 can be widened in the horizontal direction.

This STEP S5 corresponds to the step (d).

(Step S6)

Next, as shown in FIG. 2D, the insulating layer 21 is formed on the upper layer of the p-type semiconductor layer 32 at a position outside the first metal layer 19 and the second metal layer 20. As one example of a specific method, for example, a film of SiO₂ having a thickness of approximately 200 nm is formed by a sputtering method in such a state that the upper layers of the first metal layer 19 and the second metal layer 20 are masked. A material to be film-formed may be an insulating material and may be, for example, SiN or Al₂O₃.

(Step S7)

As shown in FIG. 2E, the solder diffusion preventing layer 17 is formed to cover the top surfaces of the first metal layer 19, the second metal layer 20, and the insulating layer 21. After that, the solder layer 15 is formed on the upper layer of the solder diffusion preventing layer 17. A more specific method for forming the solder diffusion preventing layer 17 and the solder layer 15 is, for example, as follows.

First, a film of Ti having a thickness of 100 nm and a film of Pt having a thickness of 200 nm are formed for 3 periods so as to cover the top surfaces of the first metal layer 19, the second metal layer 20, and the insulating layer 21 using an electron beam vapor deposition apparatus (EB apparatus), whereby the solder diffusion preventing layer 17 is formed. Further, after that, a film of Ti having a thickness of 10 nm is vapor-deposited on the top surface (Pt surface) of the solder diffusion preventing layer 17, and then Au—Sn solder made of 80% of Au and 20% of Sn is vapor-deposited in a film thickness of 3 μm, whereby the solder layer 15 is formed.

In the STEP of forming the solder layer 15, the solder layer 13 may be formed on the top surface of the support substrate 11 prepared separately from the growth substrate 61 (see FIG. 2F). The solder layer 13 may be formed of the same material as the solder layer 15. In the next STEP, the solder layer 15 and the solder layer 13 are bonded to allow the growth substrate 61 and the support substrate 11 to be applied together. As the support substrate 11, CuW is used, for example, as described above in the section “Structure”.

In FIG. 2F, a solder diffusion preventing layer for preventing diffusion of the material of the solder layer 13 is formed on the support substrate 11 with the use of a material similar to that of the solder diffusion preventing layer 17, and the solder layer 13 may be formed on an upper layer of this solder diffusion preventing layer.

(Step S8)

Next, as shown in FIG. 2G, the growth substrate 61 and the support substrate 11 are applied together. More specifically, the solder layer 15 and the solder layer 13 formed on the upper layer of the support substrate 11 are applied together at a temperature of 280° C. and under a pressure of 0.2 MPa. This STEP S8 corresponds to the step (e). As described above, when the solder layer 13 is not formed on the upper layer of the support substrate 11, the support substrate 11 and the growth substrate 61 may be applied together through the solder layer 15.

(Step S9)

Next, as shown in FIG. 2H, the growth substrate 61 is exfoliated. More specifically, KrF excimer laser is radiated from the growth substrate 61 side in such a state that the growth substrate 61 is facing upward and the support substrate 11 is facing downward, and an interface between the growth substrate 61 and the epitaxial layer 40 is decomposed, whereby the growth substrate 61 is exfoliated. While sapphire forming the growth substrate 61 allows laser to pass therethrough, GaN (non-doped layer 36) located therebelow absorbs laser, so that this interface comes to have a high temperature to decompose GaN. This exfoliates the growth substrate 61.

After that, GaN (non-doped layer 36) remaining on the wafer is removed by wet etching using hydrochloric acid or the like or by dry etching using an ICP apparatus to expose the n-type semiconductor layer 35. Through the STEP S9, the growth substrate 61 and the non-doped layer 36 are removed to leave the semiconductor layer 30 having the p-type semiconductor layer 32, the p-type semiconductor layer 31, the active layer 33, and the n-type semiconductor layer 35.

This STEP S9 corresponds to the step (f).

(Step S10)

Next, as shown in FIG. 2I, adjacent elements are separated from each other. More specifically, with respect to a boundary region to an adjacent element, the semiconductor layer 30 is etched using an ICP apparatus until the top surface of the insulating layer 21 is exposed. As described above, during this time, the insulating layer 21 functions as a stopper at the time of etching.

(Step S11)

Next, as shown in FIG. 2J, the n-side electrode (42, 43) is formed at a position of the top surface of the n-type semiconductor layer 35, that faces the second metal layer 20 in the direction perpendicular to the surface of the support substrate 11. More specifically, after forming an electrode formed of a film of Cr having a thickness of 100 nm and a film of Au having a thickness of 3 μm, sintering is carried out at 250° C. for 1 minute in a nitrogen atmosphere.

This STEP S11 corresponds to the step (g).

(Step S12)

After that, the elements are separated from each other by, for example, a laser dicing apparatus, a back surface of the support substrate 11 is bonded to a package using, for example, an Ag paste, and wire bonding is carried out onto the n-side electrode 43 as a power supply terminal. For example, the wire 45 formed of Au is connected to a bonding region of φ100 μm with a load of 50 g, whereby wire bonding is carried out. This allows that the semiconductor light-emitting element 1 shown in FIG. 1A is formed.

Notably, between the STEP S8 and the STEP S9, concavoconvexes (mesa structure) may be formed on a front surface of the n-type semiconductor layer 35 by dipping in an alkali solution such as KOH. Also, after the n-side electrode (42, 43) is formed on the top surface of the n-type semiconductor layer 35, an insulating layer may be formed so as to cover the side surface of the semiconductor layer 30.

### EXAMPLES

Hereinafter, it is verified with reference to Examples and Comparative Examples that in the semiconductor light-emitting element 1, the light extraction efficiency is further enhanced as compared with a conventional element.

<Verification of Interface Resistance>

First, it is described with reference to Examples that after the second metal layer 20 is partially formed on the top surface of the first metal layer 19 in the STEP S4, annealing is performed in the STEP S5, whereby a difference in resistance at an interface between the second metal layer 20 and the semiconductor layer 30 can be provided.

### Example 1

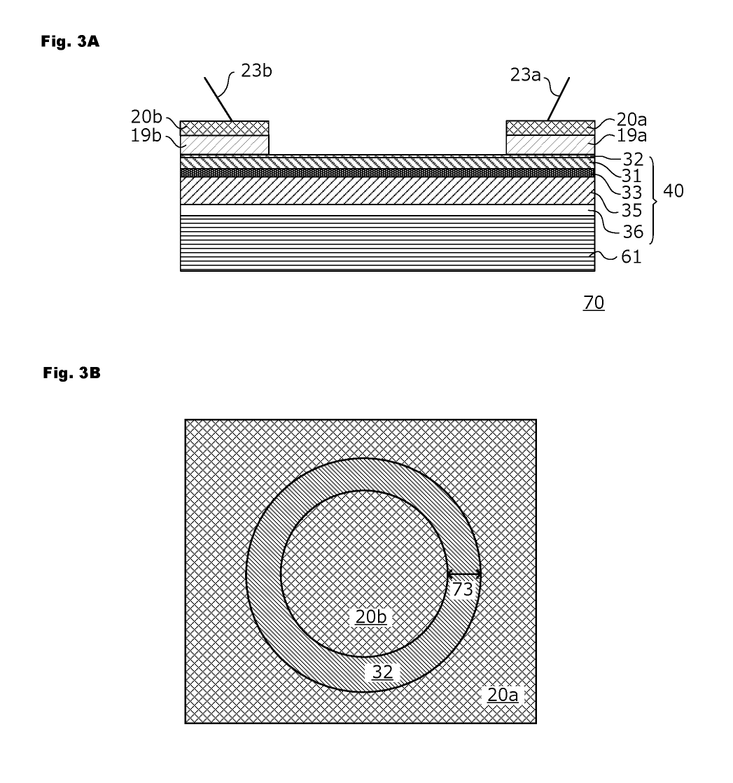

FIG. 3A is a cross-sectional view schematically showing a constitution of an evaluation element 70 produced as Example 1, and FIG. 3B is a plan view schematically showing the constitution of the evaluation element 70. The evaluation element 70 was produced by the following method. First, after the STEPs S1 and S2 were carried out, the two first metal layers 19 (19a, 19b) were formed by a method similar to the STEP S3 in a state of having a gap 73. After that, the second metal layer 20 (20a, 20b) was formed on the upper layer of the first metal layer 19 by a method similar to the STEP S4, and annealing was then performed by a method similar to the STEP S5. In the STEP S5, annealing was performed at four different temperatures, 350° C., 400° C., 450° C., and 500° C., whereby each of the evaluation elements 70 was produced.

As the evaluation elements 70 corresponding to Example 1, a plurality of elements in which distances of the gaps 73 are different from one another by 5 μm from 5 μm to 30 μm were produced.

### Example 2

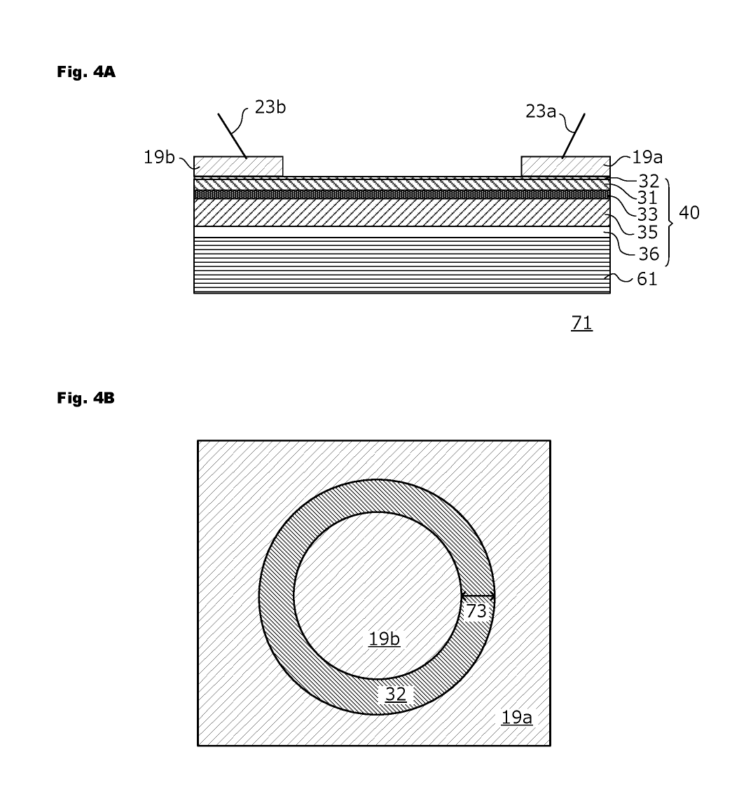

FIG. 4A is a cross-sectional view schematically showing a constitution of an evaluation element 71 produced as Example 2, and FIG. 4B is a plan view schematically showing the constitution of the evaluation element 71. The evaluation element 70 was produced by the following method. First, after the STEPs S1 and S2 were carried out, the two first metal layers 19 (19a, 19b) were formed by a method similar to the STEP S3 in a state of having the gap 73. After that, annealing was performed by a method similar to the STEP S5 without performing the STEP S4, that is, without forming the second metal layer 20. This annealing was performed at four temperatures, 350° C., 400° C., 450° C., and 500° C., as in Example 1.

As the evaluation element 71 corresponding to Example 2, a plurality of elements in which distances of the gaps 73 are different from one another by 5 μm from 5 μm to 30 μm were produced as in the evaluation element 70 corresponding to Example 1.

(Verification Results)

For the evaluation elements 70 of Example 1 having the different gaps 73, while a prover 23a was brought into contact with the second metal layer 20a, a prover 23b was brought into contact with the second metal layer 20b, and current-voltage characteristics (I-V characteristics) in a case when a voltage is applied between both electrodes through the provers 23a and 23b were obtained. This measurement method is based on a so-called TLM (Transmission Line Model) method. A resistance value of each of the evaluation elements 70 was derived from the obtained I-V characteristics, and a contact resistivity between the second metal layer 20 and the p-type semiconductor layer 32 was calculated from a relationship of the distance of the gap 73 and the resistance value of each of the evaluation elements 70.

Similarly, for the evaluation elements 71 of Example 2 having the different gaps 73, while the prover 23a was brought into contact with the first metal layer 19a, the prover 23b was brought into contact with the first metal layer 19b, and the current-voltage characteristics (I-V characteristics) in a case when a voltage is applied between both electrodes through the provers 23a and 23b were obtained. A resistance value of each of the evaluation elements 71 was derived from the I-V characteristics, and a contact resistivity between the first metal layer 19 and the p-type semiconductor layer 32 was calculated from a relationship of the distance of the gap 73 and the resistance value of each of the evaluation elements 70.

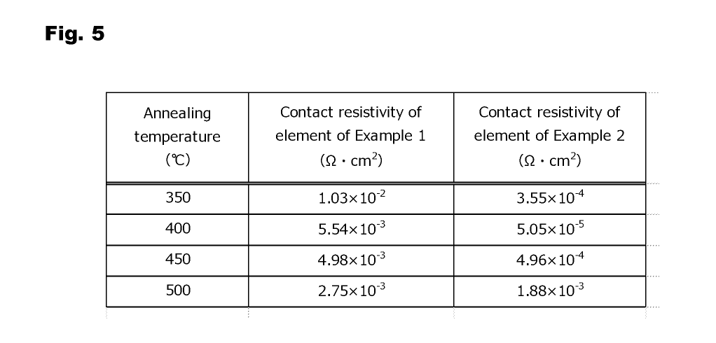

FIG. 5 is a table showing the contact resistivity in Examples 1 and 2 calculated by the above method for each annealing temperature. According to FIG. 5, it is understood that any of the contact resistivity in Example 1 at each annealing temperature is higher than the contact resistivity in Example 2. The contact resistivity in Example 1 corresponds to the resistance at the interface between the first metal layer 19 and the semiconductor layer 30, that is, the first interface 5 at a site where the second metal layer 20 is formed on the top surface of the first metal layer 19. The contact resistivity in Example 2 corresponds to the resistance at the interface between the first metal layer 19 and the semiconductor layer 30, that is, the second interface 6 at a site where the second metal layer 20 is not formed on the top surface of the first metal layer 19.

According to the results shown in FIG. 5, it is found that when annealing is performed in such a state that the second metal layer 20 is formed on the partial top surface of the first metal layer 19, a difference in resistance at the interface between the first metal layer 19 and the semiconductor layer 30 is provided. In particular, it is found that in the case where the annealing temperature is 400° C. and the case where the annealing temperature is 450° C., a difference in contact resistivity between Example 1 and Example 2 can be extremely increased as compare with the case where the annealing temperature is 350° C. and the case where the annealing temperature is 500° C. Consequently, it can be said that it is more preferable to perform annealing in the STEP S5 at not less than 400° C. and not more than 450° C.

<Verification of Light Output>

Next, it will be described with reference to Examples and Comparative Examples that a light output in the semiconductor light-emitting element 1 produced by the above method is higher than that in a conventional constitution.

### Example 3

As an element of Example 3, the semiconductor light-emitting element 1 (see FIGS. 1A to 1C) produced through the STEPs S1 to S12 was adopted.

### Comparative Example 1

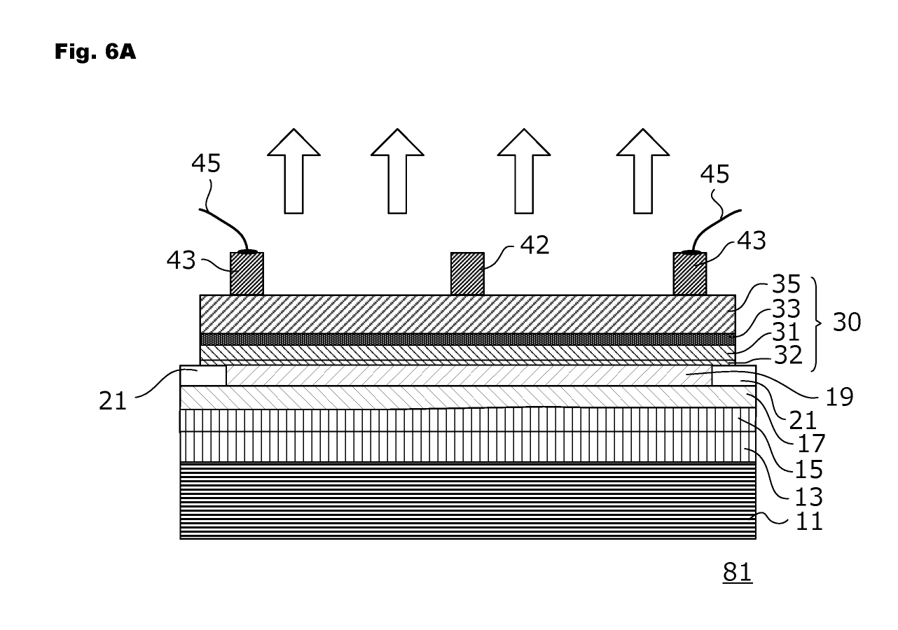

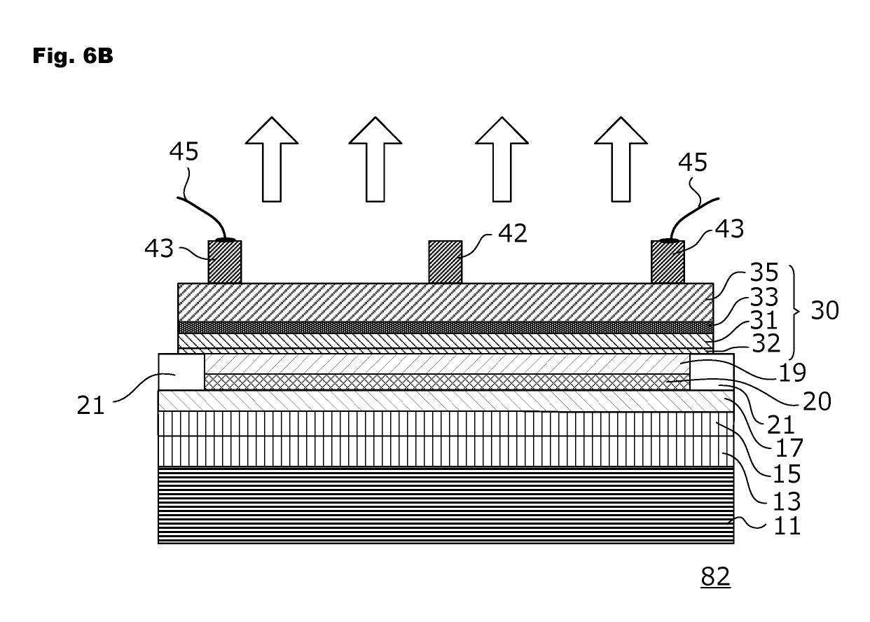

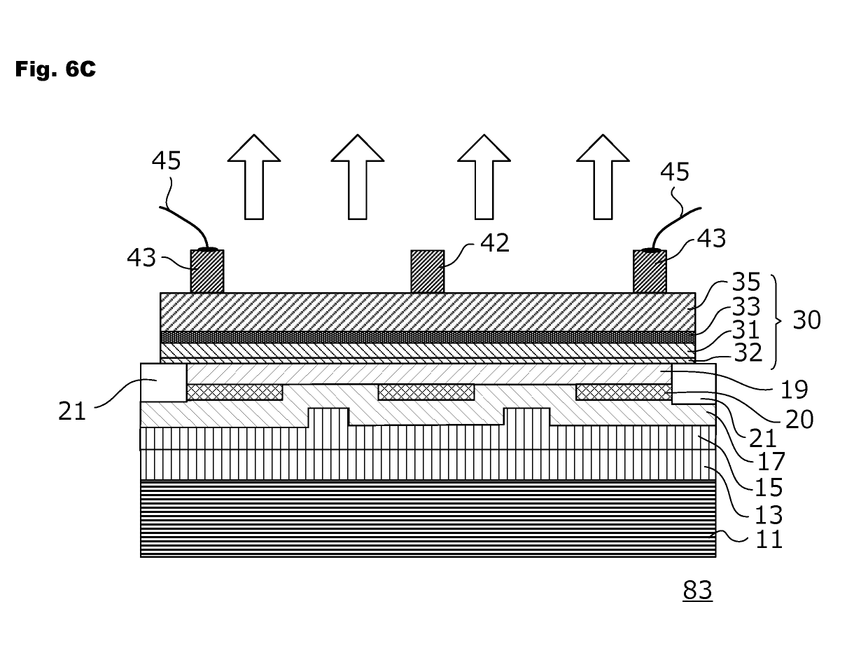

As an element of Comparative Example 1, a semiconductor light-emitting element 81 produced without carrying out the STEP S4 was adopted. Namely, the semiconductor light-emitting element of Comparative Example 1 corresponds to a semiconductor light-emitting element produced by forming the first metal layer 19, then performing annealing without forming the second metal layer 20, and then carrying out the STEPs S6 to S12. FIG. 6A is a cross-sectional view schematically showing a structure of the semiconductor light-emitting element 81 of Comparative Example 1. This constitution corresponds to a semiconductor light-emitting element in a conventional example.

### Comparative Example 2

As an element of Comparative Example 2, a semiconductor light-emitting element 82 produced by forming the second metal layer 20 on the entire top surface of the first metal layer 19, performing annealing according to the STEP S5, and then carrying out the STEPs S6 to S12 was adopted. FIG. 6B is a cross-sectional view schematically showing a structure of the semiconductor light-emitting element 82 of Comparative Example 2.

### Comparative Example 3

As an element of Comparative Example 3, a semiconductor light-emitting element 83 produced by reversing the order of the STEP S4 and the STEP S5 was adopted. Namely, the element of Comparative Example 3 corresponds to a semiconductor light-emitting element produced by forming the first metal layer 19, then forming the second metal layer 20 as in Example 1 after executing annealing, and then carrying out the STEPs S6 to S12. FIG. 6C is a cross-sectional view schematically showing a structure of the semiconductor light-emitting element 83 of Comparative Example 3. The semiconductor light-emitting element 83 of Comparative Example 3 is structurally the same as the semiconductor light-emitting element 1 of Example 3 shown in FIG. 1A.

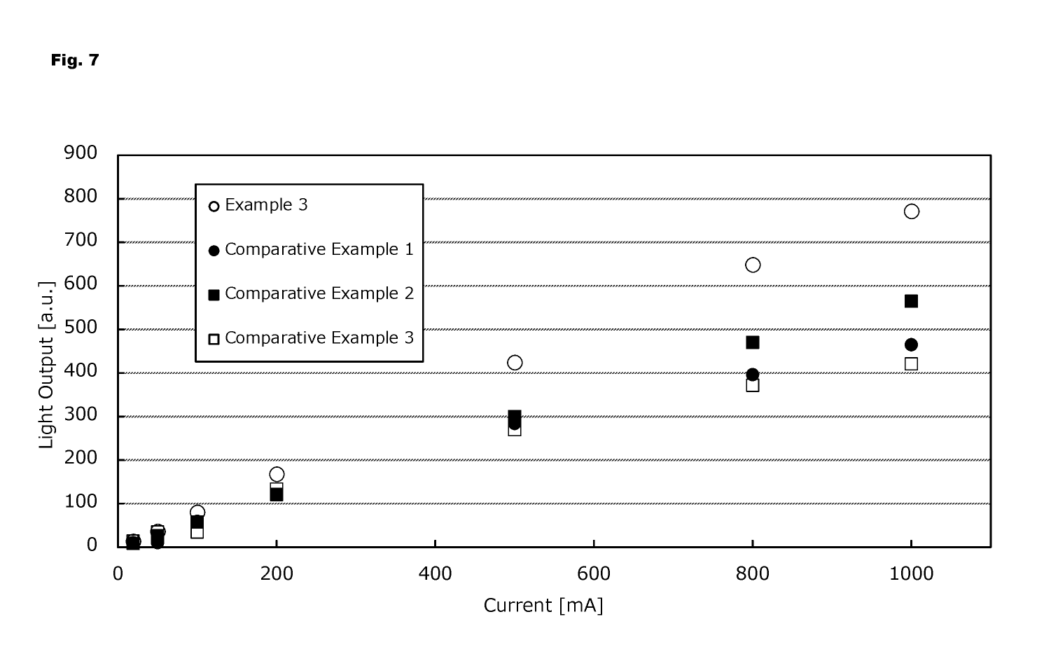

FIG. 7 is a graph showing I-L characteristics (current-light output characteristics) of the semiconductor light-emitting element 1 of Example 3 and each of the semiconductor light-emitting elements (81 to 83) of Comparative Examples 1 to 3. FIG. 7 shows that the light output in the semiconductor light-emitting element of Example 3 is extremely higher than that in each of the semiconductor light-emitting elements of Comparative Examples 1 to 3.

In the semiconductor light-emitting element 81 of Comparative Example 1, a high resistance material is not formed vertically below the n-side electrode (42, 43), so that it is considered that a current relatively easily flows into the semiconductor layer 30 along the direction perpendicular to the surface of the support substrate 11. As a result, it is inferred that in the semiconductor light-emitting element 81 of Comparative Example 1, a large amount of current flows in a limited region in the active layer 33, and a light-emitting region is restricted, whereby the light output is lower than that in the semiconductor light-emitting element 1 of Example 3.

In the semiconductor light-emitting element 82 of Comparative Example 2, the second metal layer 20 is formed in contact with the entire surface of the first metal layer 19. As a result, a resistance at an interface between the first metal layer 19 and the semiconductor layer 30 is high as a whole. Namely, since a site where a resistance is low and a site where a resistance is high are not formed at the interface between the first metal layer 19 and the semiconductor layer 30, it is therefore considered that a current relatively easily flows into the semiconductor layer 30 along the direction perpendicular to the surface of the support substrate 11.

The semiconductor light-emitting element 83 of Comparative Example 3 is produced by performing annealing before forming the second metal layer 20. Thus, even if the second metal layer 20 is formed at a portion of a top surface of the first metal layer 19 after annealing, a resistance at an interface between the first metal layer 19 and a semiconductor layer 30 is determined at the time of annealing. Thus, the semiconductor light-emitting element 31 of Comparative Example 3 is in a state substantially similar to that of the semiconductor light-emitting element 81 of Comparative Example 1. Namely, since a high resistance material is not formed vertically below an n-side electrode (42, 43), so that it is considered that a current relatively easily flows into the semiconductor layer 30 along a direction perpendicular to a surface of a support substrate 11.

On the other hand, in the semiconductor light-emitting element 1 of Example 1, the first interface 5 having a high resistance value is formed at a position vertically below the n-side electrode (42, 43) at the interface between the first metal layer 19 and the semiconductor layer 30, and the second interface 6 having a resistance value lower than that of the first interface 5 is formed at a site other than this. Thus, the current becomes less likely to flow into the semiconductor layer 30 in the direction perpendicular to the surface of the support substrate 11, and the path of the current flowing into the active layer 33 can be widened in the horizontal direction. Consequently, it is considered that the light-emitting region in the active layer 33 is widened in the horizontal direction, and high light output is achieved.

<Verification of Relationship Between Width of n-Side Electrode (42, 43) and Width of Second Metal Layer 20>

A plurality of the semiconductor light-emitting elements 1 were produced by carrying out the STEPs S1 to S12 while changing a relationship between the width d of the n-side electrode (42, 43) and the width D of the second metal layer 20.

### Example 4

While the width d of the n-side electrode (42, 43) was set to 10 μm, the width D of the second metal layer 20 was set to 30 μm, and the semiconductor light-emitting element 1 was produced. At that time, a value of d/D was 33%.

### Example 5

While the width d of the n-side electrode (42, 43) was set to 20 μm, the width D of the second metal layer 20 was set to 50 μm, and the semiconductor light-emitting element 1 was produced. At that time, the value of d/D was 40%.

### Example 6

While the width d of the n-side electrode (42, 43) was set to 15 μm, the width D of the second metal layer 20 was set to 30 μm, and the semiconductor light-emitting element 1 was produced. At that time, the value of d/D was 50%.

### Example 7

While the width d of the n-side electrode (42, 43) was set to 20 μm, the width D of the second metal layer 20 was set to 30 μm, and the semiconductor light-emitting element 1 was produced. At that time, the value of d/D was 67%.

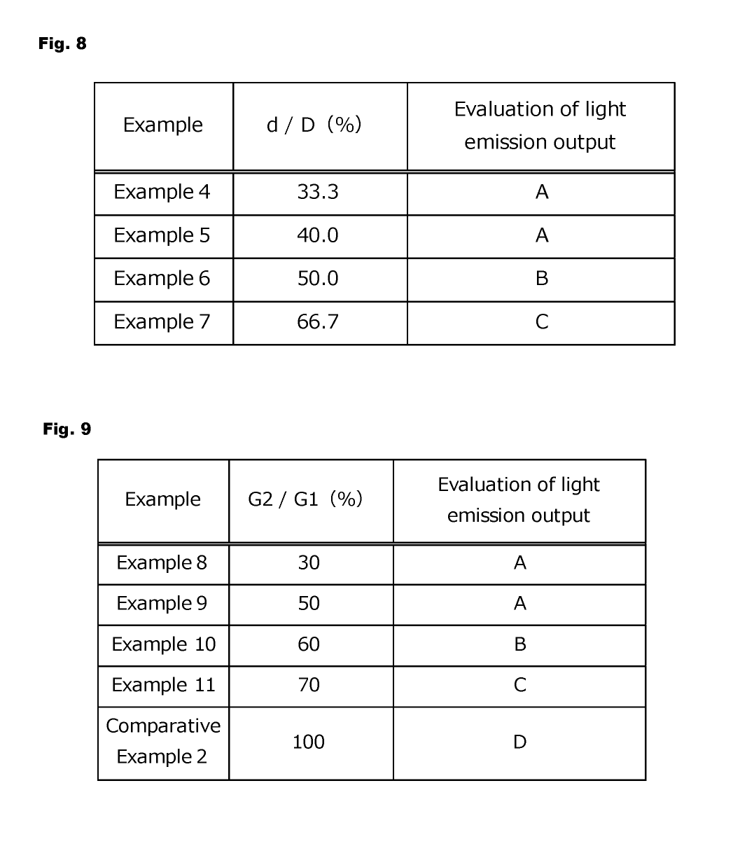

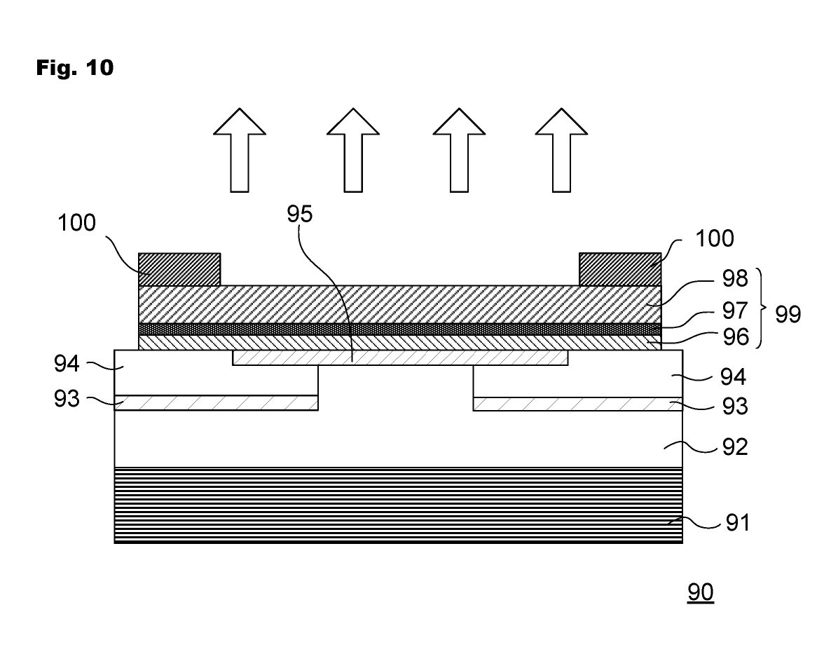

FIG. 8 is a table comparing light outputs of semiconductor light-emitting elements 1 of Examples 4 to 7. The evaluation results are as follows. An element in which the light output has been extremely enhanced as compared with the semiconductor light-emitting element 81 of Comparative Example 1 corresponding to a conventional element is evaluated as “A”. Although not to the same extent as the element evaluated as “A”, an element in which the light output has been enhanced as compared with the semiconductor light-emitting element 81 of Comparative Example 1 is evaluated as “B”. An element in which the light output has been only slightly enhanced as compared with the semiconductor light-emitting element 81 of Comparative Example 1 is evaluated as “C”.

FIG. 8 shows that the light outputs of the semiconductor light-emitting elements 1 of Examples 4 and 5 are high, the light output of the semiconductor light-emitting element 1 of Example 6 is next high, and the light output of the semiconductor light-emitting element 1 of Example 7 is lowest. Namely, it is considered that if a value of the width d of the n-side electrode (42, 43) to the width D of the second metal layer 20 is more than 50%, the effect of enhancing the light output of the semiconductor light-emitting element 1 cannot be sufficiently obtained.

As described above, in the annealing step in the STEP S5, an amount of oxygen introduced into the site of the first metal layer 19 in which the second metal layer 20 is formed on its upper layer is small as compared with the site of the first metal layer 19 whose top surface is exposed. As a result, the resistance at the interface between the first metal layer 19 and the semiconductor layer 30 at the former site of the first metal layer 19 is higher than that at the latter site of the first metal layer 19. However, since oxygen is actually introduced also from the lateral side of the second metal layer 20, the resistance at the interface between the first metal layer 19 and the semiconductor layer 30 does not become high in the entire first metal layer 19 whose top surface is covered by the second metal layer 20. Namely, it is considered that a contact is formed at a site near an outer edge of the first metal layer 19 by oxygen introduced from the lateral side of the second metal layer 20.

Thus, in view of the fact that oxygen flows from the lateral side of the second metal layer 20, the case where the width D of the second metal layer 20 is set to be sufficiently larger than the width d of the n-side electrode (42, 43) will be considered. At this time, even if oxygen is flowed inside from an outer edge of the second metal layer 20, a sufficient amount of oxygen is not supplied near the center of the second metal layer 20 in the direction parallel to the surface of the support substrate 11, that is, near the position vertically facing the n-side electrode (42, 43).

In view of the results shown in FIG. 8, it is considered that it is preferable that a value of the width d of the n-side electrode (42, 43) to the width D of the second metal layer 20 is set to not more than 50%, and namely, the value of the width D of the second metal layer 20 to the width d of the n-side electrode (42, 43) is set to be twice or more. In other words, it can be said that it is preferable that a contact area between the n-type semiconductor layer 35 and the n-side electrode (42, 43) is set to not more than 50% of a contact area between the second metal layer 20 and the first metal layer 19 at the position facing the n-side electrode in the direction perpendicular to the surface of the support substrate 11. This allows that the resistance at the interface between the first metal layer 19 and the semiconductor layer 30 at the position vertically facing the n-side electrode (42, 43) is set to be higher than that at the position not vertically facing the n-side electrode (42, 43).

<Verification of Area Ratio of First Metal Layer 19 and Second Metal Layer 20>

A plurality of the semiconductor light-emitting elements 1 were produced by carrying out the STEPs S1 to S12 while changing an area of the second metal layer 20 formed in the STEP S4.

### Example 8

While an area G1 of the first metal layer 19 was set to 940000 μm², a total area G2 of the second metal layer 20 was set to 282000 μm², and a semiconductor light-emitting element 1 was produced. At that time, a value of G2/G1 was 30%. In the following examples 9 to 11, the area G1 of the first metal layer 19 is common.

### Example 9

The total area G2 of the second metal layer 20 was set to 470000 μm². At that time, the value of G2/G1 was 50%.

### Example 10

The total area G2 of the second metal layer 20 was set to 565000 μm². At that time, the value of G2/G1 was 60%.

### Example 11

The total area G2 of the second metal layer 20 was set to 660000 μm². At that time, the value of G2/G1 was 70%.

### Comparative Example 2

The total area G2 of the second metal layer 20 was set to 940000 μm². An element produced under this condition is a semiconductor light-emitting element produced by forming the second metal layer 20 on the entire top surface of the first metal layer 19, performing annealing according to the STEP S5, and then carrying out the STEPs S6 to S12 and corresponding to the semiconductor light-emitting element 82 of Comparative Example 2. At that time, the value of G2/G1 was 100%.

FIG. 9 is a table comparing the light outputs of the semiconductor light-emitting elements 1 of Examples 8 to 11 and the semiconductor light-emitting element 82 of Comparative Example 2. The contents of the evaluations, “A”, “B”, and “C” are similar to those in FIG. 8. As compared with the semiconductor light-emitting element 81 of Comparative Example 1, an element having an equivalent light output is evaluated as “D”.

The semiconductor light-emitting element 82 of Comparative Example 2 exhibited an extremely low light output as compared with the semiconductor light-emitting elements 1 of Examples 8 to 11. This reason is as described above. The semiconductor light-emitting element 1 of Example 11 exhibited a slightly low light output as compared with the semiconductor light-emitting elements 1 of Examples 8 to 10. Among Examples 8 to 10, the semiconductor light-emitting element 1 of Examples 8 and 9 exhibited a highest light output. Although the semiconductor light-emitting element 1 of Example 10 exhibited a light output lower than the light outputs of Examples 8 and 9, it exhibited a light output higher than the light output of Example 11.

The above results suggest that if the second metal layer 20 is formed on the top surface of the first metal layer 19 over a wide range, a region where the first interface 5 having a high contact resistance is formed is extremely increased, whereby the effect of horizontally widening the current flowing into the semiconductor layer 30 is suppressed. From the results shown in FIG. 9, it can be said that it is preferable that a ratio (G2/G1) of the area G2 of the second metal layer 20 to the area G1 of the first metal layer 19 is set to be not more than 60%.

### Another Embodiment

Hereinafter, another embodiment will be described.

<1> In the above embodiment, the semiconductor light-emitting element 1 is constituted to include the second metal layer 20. However, as described above in the section “Production Method”, the second metal layer 20 is provided in order to cause a difference in oxygen introduction amount by covering a portion of the top surface of the first metal layer 19 at the time of the annealing step according to the STEP S5. Thus, after completion of the annealing step according to the STEP S5, the second metal layer 20 may be removed.

<2> The above constitutions and production methods are just examples of the embodiment, so that there is no need to provide all of these constructions and steps. For example, the solder layer 17 is formed for efficiently applying the growth substrate 61 and the support substrate 11 together, so that the solder layer 17 is not necessarily needed in achieving the function of the semiconductor light-emitting element 1 as long as the two substrates can be applied together.

<3> In the present specification, expression that a layer B is formed “on an upper layer” or “above” a layer A includes a constitution in which when an element is rotated or turned upside down, the layer B is located on the upper layer or above the layer A. Similarly, in the present specification, expression that a layer B is formed “on a lower layer” or “below” a layer A includes a constitution in which when an element is rotated or turned upside down, the layer B is located on the lower layer or below the layer A. The same thing applies to expressions, “top surface” and “bottom surface”.

In the above embodiment, the constitution in which the p-type semiconductor layer (31, 32) is in contact with the first metal layer 19, and light is extracted from the n-type semiconductor layer 35 side has been described. However, a constitution in which the positions of the p-type semiconductor layer and the n-type semiconductor layer are reversed may be adopted.

### DESCRIPTION OF REFERENCE SIGNS

1: semiconductor light-emitting element
5: first interface
6: second interface
11: support substrate
13: solder layer
15: solder layer
17: solder diffusion preventing layer
19 (19a, 19b): first metal layer
20 (20a, 20b): second metal layer
21: insulating layer
23a, 23b: prover
30: semiconductor layer
31: p-type semiconductor layer
32: p-type semiconductor layer
33: active layer
35: n-type semiconductor layer
36: non-doped layer
40: epitaxial layer
42: n-side electrode
43: n-side electrode
45: wire
61: growth substrate
70: evaluation element
71: evaluation element
73: gap
81: semiconductor light-emitting element of Comparative Example 1
82: semiconductor light-emitting element of Comparative Example 2
83: semiconductor light-emitting element of Comparative Example 3
90: conventional semiconductor light-emitting element
91: support substrate
92: conductive layer
93: reflective film
94: insulating layer
95: reflective electrode
96: p-type semiconductor layer
97: active layer
98: n-type semiconductor layer
99: semiconductor layer
100: n-side electrode

1. (canceled)

2. A method for producing a semiconductor light-emitting element, comprising:
a step (a) of forming a semiconductor layer including an active layer on an upper layer of a growth substrate,
a step (b) of forming a first metal layer on a top surface of the semiconductor layer,
a step (c) of forming a second metal layer on a portion of a top surface of the first metal layer without preforming annealing after the step (b), and
a step (d) of performing annealing after the step (c), wherein the step (a) has a step of forming an n-type or p-type first semiconductor layer on the upper layer of the growth substrate, a step of forming the active layer on an upper layer of the first semiconductor layer, and a step of forming, on an upper layer of the active layer, a second semiconductor layer of a conductive type different from that of the first semiconductor layer, and the method further comprising:
after the step (d), a step (e) of forming a support substrate on the upper layers of the first metal layer and the second metal layer;
a step (f) of exfoliating the growth substrate; and
a step (g) of forming a first electrode on a top surface of the first semiconductor layer on the opposite side of the active layer at a position facing the second metal layer in a direction perpendicular to a surface of the support substrate.

3. The method for producing a semiconductor light-emitting element according to claim 2, wherein
the first metal layer comprises a material containing Ag, and
the second metal layer comprises a material containing at least one of Ti, Pt, Mo, Rh, Cu, Au, Mg, Ni, and W.

4. A semiconductor light-emitting element, which has, on a support substrate, an n-type or p-type first semiconductor layer, a second semiconductor layer of a conductive type different from that of the first semiconductor layer, and an active layer formed between the first semiconductor layer and the second semiconductor layer, comprising:
a first electrode formed in contact with a top surface of the first semiconductor layer;
a first metal layer formed in contact with a bottom surface of the second semiconductor layer; and
a second metal layer formed in contact with a bottom surface of the first metal layer at a position facing the first electrode in a direction perpendicular to a surface of the support substrate,
wherein at an interface between the first metal layer and the second semiconductor layer, a resistance at a first interface at a position facing the second metal layer in the direction perpendicular to the surface of the support substrate is higher than a resistance at a second interface at a position not facing the second metal layer in the direction.

5. The semiconductor light-emitting element according to claim 4, wherein the first metal layer comprises a material containing Ag, and
the second metal layer comprises a material containing at least one of Ti, Pt, Mo, Rh, Cu, Au, Mg, Ni, and W.

6. The semiconductor light-emitting element according to claim 4, wherein the entire top surface of the first metal layer is in contact with a bottom surface of the second semiconductor layer.

7. The semiconductor light-emitting element according to claim 6, wherein a total area of a region where the second metal layer is in contact with the bottom surface of the first metal layer is not more than 60% of an area of the second semiconductor layer.

8. The semiconductor light-emitting element according to claim 4, wherein a contact area between the first semiconductor layer and the first electrode is not more than 50% of a contact area between the second metal layer and the first metal layer at the position facing the first electrode in the direction perpendicular to the surface of the support substrate.

9. The semiconductor light-emitting element according to claim 5, wherein the entire top surface of the first metal layer is in contact with a bottom surface of the second semiconductor layer.

10. The semiconductor light-emitting element according to claim 9, wherein a total area of a region where the second metal layer is in contact with the bottom surface of the first metal layer is not more than 60% of an area of the second semiconductor layer.

11. The semiconductor light-emitting element according to claim 5, wherein a contact area between the first semiconductor layer and the first electrode is not more than 50% of a contact area between the second metal layer and the first metal layer at the position facing the first electrode in the direction perpendicular to the surface of the support substrate.

12. The semiconductor light-emitting element according to claim 6, wherein a contact area between the first semiconductor layer and the first electrode is not more than 50% of a contact area between the second metal layer and the first metal layer at the position facing the first electrode in the direction perpendicular to the surface of the support substrate.

13. The semiconductor light-emitting element according to claim 7, wherein a contact area between the first semiconductor layer and the first electrode is not more than 50% of a contact area between the second metal layer and the first metal layer at the position facing the first electrode in the direction perpendicular to the surface of the support substrate.
